(19) United States
(12) Patent Application Publication
(10) Pub. No.: US 2026/0088076 A1
(43) Pub. Date: Mar. 26, 2026

(54) ADJUSTING TRAINING DELAYS IN SDRAM

(71) Applicant: Advanced Micro Devices, Inc., Santa Clara, CA (US)

(72) Inventor: Lu HUANG, Shanghai (CN)

(21) Appl. No.: 18/898,466

(22) Filed: Sep. 26, 2024

(51) Int. Cl. G11C 11/4076; G11C 11/4096

(52) U.S. Cl. CPC G11C 11/4076; G11C 11/4096

(57) ABSTRACT

Embodiments herein describe techniques for providing individual clock delay values to each rank coupled to a memory controller. A register (e.g., a mode register (MR)) can store an offset delay for each of the ranks relative to a minimum clock delay of the ranks. For example, the memory controller can calculate the clock delay for each rank and then find the difference (or delta) between the individual clock delay values and the minimum clock delay value. The memory controller can write these difference/deltas to the registers for the ranks. The ranks can then use the value stored in their respective registers to further delay a received clock signal that has already been delay by the minimum clock delay value.

### TECHNICAL FIELD

The embodiments presented herein relate to providing different training delays to different ranks of SDRAM.

### BACKGROUND

Memory systems (e.g., dynamic random access memory (DRAM)) often use two differential forwarded clocks that are source synchronous to data signals. However, as these clock and data signals are processed, they can be misaligned with can cause write errors.

### SUMMARY

One embodiment described herein is a memory controller that includes a clock source configured to output a clock signal to a plurality of ranks and a level trainer. The level trainer includes circuitry configured to perform level training to generate a first clock delay for a first rank of the plurality of ranks, perform level training to generate a second clock delay for a second rank of the plurality of ranks where the first clock delay is less than the second clock delay, write a delta between the second clock delay and the first clock delay in a register in the second rank, and transmit a clock signal to both the first and second ranks that is delayed by the first clock delay where the second rank is configured to further delay the clock signal using the delta written in the register.

Another embodiment described herein is a method that includes performing level training to generate a first clock delay for a first rank of a plurality of ranks of memory chips, performing level training to generate a second clock delay for a second rank of the plurality of ranks of memory chips where the first clock delay is less than the second clock delay, write a delta between the second clock delay and the first clock delay in a register in the second rank, and transmit a clock signal to both the first and second ranks that is delayed by the first clock delay where the second rank is configured to further delay the clock signal using the delta written in the register.

Another embodiment described herein is a memory system that includes a plurality of ranks each comprising a plurality of memory chips and a memory controller. The memory controller is configured to perform level training to generate a first clock delay for a first rank of the plurality of ranks, perform level training to generate a second clock delay for a second rank of the plurality of ranks where the first clock delay is less than the second clock delay, write a delta between the second clock delay and the first clock delay in a register in the second rank, and transmit a clock signal to both the first and second ranks that is delayed by the first clock delay where the second rank is configured to further delay the clock signal using the delta written in the register.

### BRIEF DESCRIPTION OF DRAWINGS

FIG. 1 illustrates a memory system that provides individual delays to ranks of DRAM chips, according to one embodiment herein.

FIG. 2 is a flowchart for providing delays to compensate for CK-to-WCK timing skew affecting WCK2CK synchronous operation, according to one embodiment herein.

FIG. 3 illustrates adjusting WCK using a delay in a DRAM chip, according to one embodiment herein.

FIG. 4 illustrates a MR for storing an delay to compensate for CK-to-WCK timing skew, according to one embodiment herein.

FIG. 5 is a flowchart for providing delays to compensate for CK-to-WCK timing skew affecting WCK2CK synchronous operation, according to one embodiment herein.

FIG. 6 depicts a block diagram illustrating a computing system, according to one embodiment herein.

### DETAILED DESCRIPTION

LPDDR5 SDRAM's (Low-Power Double Data Rate Synchronous Dynamic Random Access Memory) command and address interface operates from a differential clock (CK_t and CK_c) (referred to as simply “CK” or “command clock”). The data interface uses two differential forwarded clocks (WCK_t/WCK_c) (referred to as simply “WCK” or “data clock”) that are source synchronous to data signals (e.g., DQs). That is, the CK and the WCK are synchronized by a memory controller where the same clock source (e.g., a phase-locked loop (PLL)) in the memory controller is used to generate both the CK and the WCK.

In LPDDR5 SDRAM, the WCK has a frequency that is typically two or four times faster than the CK. The faster WCK is used to transfer data between the WCK and the SDRAM device at greater speeds (to increase bandwidth). However, the SDRAM typically reduces the WCK when used internally. For example, LPDDR5 SDRAM can include a clock divider in the WCK clock tree. By dividing the WCK, the operation speed of DRAM internal circuits in WCK domain is reduced to half (or more). However, the WCK divider initial state is unpredictable and can result in the WCK no longer being aligned (or synchronized) with the CK within the SDRAM (referred to as a misaligned CK state).

To adjust the CK-to-WCK relationship and guarantee WCK to CK (WCK2CK) synchronous operation, SDRAM provides a WCK2CK leveling feature to compensate for CK-to-WCK timing skew affecting WCK2CK synchronous operation. A memory controller can use the WCK2CK Leveling feature to generate a delay (referred to herein as a training WCK delay or “Twckdly”) for the WCK so that it is synchronized with the CK. However, different ranks of SDRAM chips (e.g., memory chips) may need different Twckdly values due to, e.g., different trace lengths or differences in the manufacturing process. However, because of limited input/output (IO) space, a memory controller may have only one IO pin or data path for a Twckdly that has to be shared by each rank. While a memory controller could average the Twckdly values for the ranks and then use the average Twckdly value for each of the ranks, this results in suboptimal read and write margins, especially for the ranks with Twckdly values that are quite different from the average value.

Embodiments herein describe techniques for providing individual Twckdly values to each rank coupled to a memory controller, without having a separate IO interface for each rank. For example, the data signals (e.g., DQs), command and address bus, clocks, and other signals are shared by the ranks coupled to the memory controller. That is, the ranks share the same data bus, and receive the same commands and clock signals from the memory controller. The Twckdly can be used to delay the WCK bus, which means the WCK is delayed by the same Twckdly value when it is received at each of the ranks. The embodiments herein describe using a mode register (MR) that can store an offset delay for each of the ranks. For example, the memory controller can calculate the Twckdly for each rank and then find the difference (or delta) between the individual Twckdly values and the minimum Twckdly value. The memory controller can write these differences/deltas to the MRs for the ranks and then transmit the minimum Twckdly value to each of the ranks using a shared IO pin. The ranks can then use the value stored in their respective MR to adjust the received, minimum Twckdly value to the individual Twckdly value. That is, when receiving the WCK, the controller can have already delayed this signal by the minimum Twckdly value. The ranks can then add their customized difference/delta values to WCK to generate their individual Twckdly values. In this manner, each of the ranks can use an individual (or customized) Twckdly value to perform read and writes, rather than using an average or some other sub-optimal shared Twckdly value.

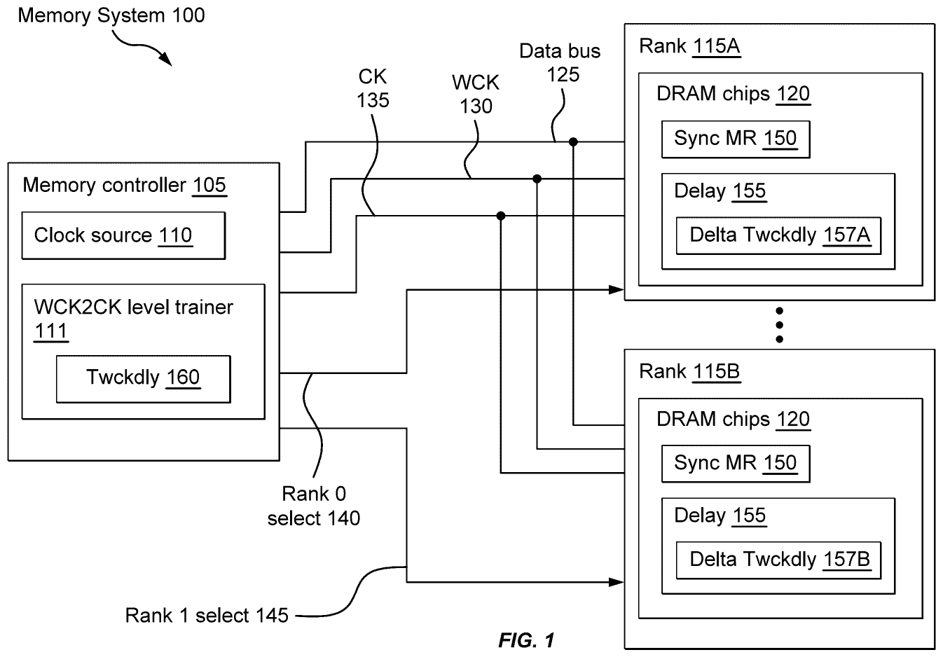

FIG. 1 illustrates a memory system 100 that provides individual delays to ranks 115 of DRAM chips 120 (e.g., memory chips), according to one embodiment herein. The system 100 includes a memory controller 105 and multiple ranks 115. The memory controller 105 provides clock signals (e.g., WCK 130 and CK 135), provides write data and receives read data via a data bus 125, and controls rank select signals 140 and 145.

The memory controller 105 includes a clock source 110 and a WCK2CK level trainer 111. In one embodiment, the clock signals WCK 130 and CK 135 are derived from the same clock source 110 (e.g., the same PLL). For example, the clock source 110 may output the CK 135 which is then multiplied to result in the faster WCK 130. In this manner, when output by the memory controller 105, the CK 135 and the WCK 130 are synchronized since they originated from the same clock source 110, and thus, can be referred to as being source synchronized. However, for any number of reasons (such as dividing the WCK in the DRAM chips 120), the WCK and the CK can become misaligned at the DRAM chips 120 (if the system 100 did not use Twckdly values to prevent this misalignment).

The WCK2CK level trainer 111 can include circuitry for calculating Twckdly values for the ranks 115. As discussed above, the WCK2CK level trainer 111 can generate delays (Twckdly values) for the WCK so that it remains synchronized with the CK at each rank 115. That is, different ranks 115 may need different Twckdly values due to, e.g., different trace lengths or differences in the manufacturing process.

In one embodiment, the WCK2CK Leveling training includes two parts: fine and coarse. The goal of WCK2CK leveling fine phase training is to align a rising edge of WCK 130 with the rising edge of the CK 135 at each rank 115. Write Leveling fine phase training compensates for any analog phase differences between CK 135 and WCK 130 distribution. The fine training ensures that the edges are aligned correctly, but not necessarily at the correct write column address strobe/signal (WCAS) latency. The coarse part of Write Leveling training calculates the delay to ensure the edges align with the correct WCAS latency. The Twckdly is the training result of WCK2CK leveling training. Using this two part processing, the WCK2CK level trainer 111 can determine a Twckdly value for each rank 115, which may be different.

Although the WCK2CK level trainer 111 determines individual Twckdly values for the ranks 115, in FIG. 1 the system 100 delays the WCK 130 using the same Twckdly 160. That is, the same Twckdly 160 is used to delay the WCK 130 sent to each of the ranks 115 coupled to the memory controller 105. Moreover, in FIG. 1, all the signals transmitted between the ranks 115 and the memory controller 105 are shared except for a rank 0 select signal 140 for selecting rank 115A and a rank 1 select signal 145 for selecting rank 115B.

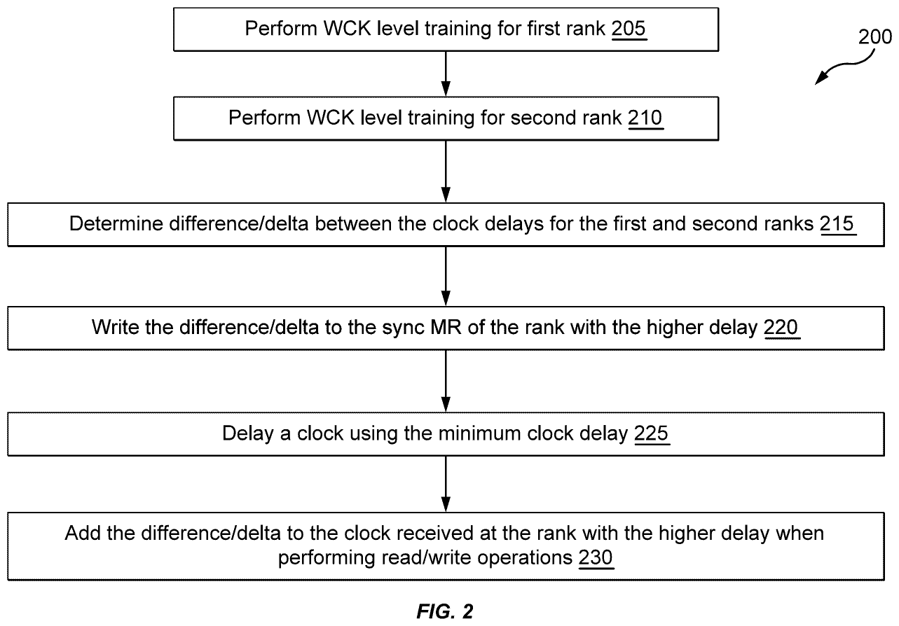

To provide the individual Twckdly values to the ranks 115, the DRAM chips 120 include sync MRs 150 which can store delay offsets that indicate the difference or delta between the Twckdly 160 (e.g., a minimum Twckdly 160) used to delay the WCK 130 and the individual Twckdly value for that particular rank. Stated differently, the DRAM chips 120 can use the value in the sync MR 150 to adjust the WCK 130 so the total delay of WCK 130 matches the individual Twckdly value for that rank. This is discussed in more detail in FIG. 2 below.

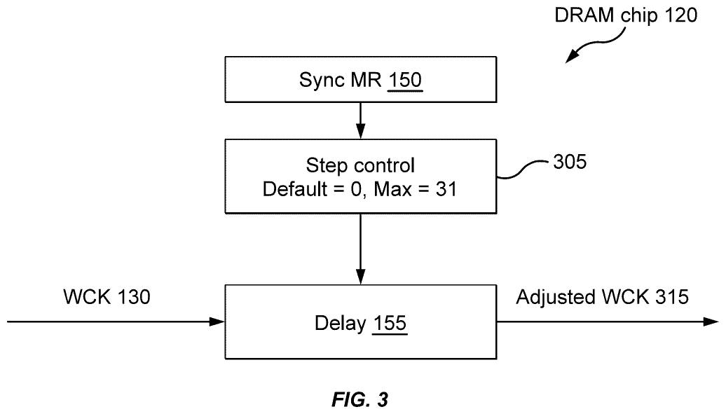

The DRAM chips 120 also include a delay 155 (e.g., a delay circuitry or delay cell) which can further delay the WCK 130 using a delta Twckdly 157 (which is determined from the value of the sync MR 150) so the total delay of WCK 130 matches the individual or customized Twckdly value that was calculated by the WCK2CK level trainer 111 for that rank 115. That is, the rank 115A can use delay 155 to add a delta Twckdly 157A to the minimum Twckdly 160 while the rank 115B can use the delay 155 to add a delay Twckdly 157B to the minimum Twckdly 160. Notably, if the delay for one of the ranks is the minimum Twckdly value, then the delta Twckdly 157 for that rank is zero (since no further delay is needed for that rank). This is described in more detail in FIG. 3.

A memory rank 115 is a set of DRAM chips 120 connected to the same chip select (e.g., rank 0 select signal 140 or rank 1 select signal 145). In one embodiment, each DRAM chip, regardless of which rank 115 it is in, shares the other command and control signals, and only the chip select pins for each rank which drive the rank select signals 140 and 145 are separate.

In one embodiment, the ranks 115 can be accessed independently, although not simultaneously as the data lines of the data bus 125 are still shared between ranks 115 on a channel. For example, the controller 105 can send write data to the rank 115A while the controller 105 waits for read data previously selected from the rank 115B. While the write data is consumed from the data bus 125 by rank 115A, the other rank 115B could perform read-related operations such as the activation of a row or internal transfer of the data to the output drivers (but could not use the data bus 125). Once the Command/Address bus is free from the previous read, the DRAM can drive out the read data using the data bus 125. Controlling interleaved accesses like so is done by the memory controller 105.

Moreover, LPDDR5 SDRAM supports WCK Always on Mode as a Mode Register Set (MRS) option, which is also referred to as a WCK free running mode. The Always on Mode is enabled by setting MR18 OP[4]=1B. When this mode is enabled, the WCK buffer in an LPDDR5 SDRAM is turned on with WCK2CK synchronization and keeps being turned on until SDRAM receives power down, self-refresh power-down or deep-sleep commands or reset. Without this mode, the WCK2CK level trainer has to recalculate the Twckdly values each time the memory system 100 “wakes up” and before performing another read or write. In the Always on Mode, the memory controller 105 keeps WCK 130 toggling (e.g., active) at its full rate after WCK2CK synchronization regardless of DQ operation. Thus, WCK2CK synchronization does not have to be repeated when the memory controller 105 determines to perform a new read or write. By remaining in the Always on Mode, the memory controller 105 could save the time to sync WCK between two read or write commands, because it only has to sync once. However, the ranks 115 have to share the Twckdly 160 in the Always on Mode which means the memory controller 105 cannot switch Twckdly between rank 115A and rank 115B, therefore both ranks 115 share the same Twckdly value. In a real implementation, it is unlikely that each rank 115 coupled to the memory controller 105 would have the same Twckdly value. As such, the embodiments herein can be used to provide the different Twckdly values to the ranks 115 while in the Always on Mode. However, the embodiments herein are not limited to the Always on Mode as there may be other modes or operations where it is advantageous to provide a shared Twckdly value to the ranks 115 but still enable the ranks 115 to determine their individual Twckdly values using the sync MRs 150 and the delays 155.

Further, while FIG. 1 illustrates two ranks 115, the memory controller 105 may be coupled to many more ranks 115 that include DRAM chips that also share the other command and control signals, but the chip/rank select pins for each rank are separate.

FIG. 2 is a flowchart of a method 200 for providing delays to compensate for CK-to-WCK timing skew affecting WCK2CK synchronous operation, according to one embodiment herein. At block 205, a WCK2CK level trainer in a memory controller (e.g., the WCK2CK level trainer 111 in FIG. 1) performs WCK level training for a first rank to determine a corresponding Twckdly value.

At block 210, the WCK2CK level trainer performs WCK level training for a second rank to determine a corresponding Twckdly value. In method 200, it is assumed these Twckdly values are different for the two ranks, which are coupled to the same memory controller.

At block 215, the WCK2CK level trainer determines a difference (or delta) between the clock delays (e.g., the Twckdly values) for the first and second ranks.

At block 220, the memory controller writes this difference or delta to a sync MR of the rank with the higher delay. For example, if the first rank has the higher Twckdly value, then the memory controller writes the delta between the Twckdly value of the first and second ranks into the sync MR (e.g., the sync MR 150 in FIG. 1) for the first rank. In this example, the memory controller may not write any value into the sync MR for the second rank (or may write a default value that indicates the delta Twckdly value is zero).

At block 225, the memory controller delays a clock (e.g., the WCK) using the minimum clock delay (e.g., the smallest Twckdly value of the ranks) when transmitting the clock to the first and second ranks. In one embodiment, the clock is transmitted using a shared IO pin such that both ranks receive the same delayed clock.

At block 230, the first rank adds the difference/delta stored in its sync MR to the clock when performing read or write operations. Put differently, the ranks can further delay the clock using their local difference/delta values indicated in the sync MR. In this example, the first rank uses the delta in its sync MR to further delay the clock received from the memory controller so that the total delay of the clock is the first rank's individual (or customized) Twckdly value. In this example, the second rank may not have to further delay the clock received from the memory controller, since the minimum clock delay is its Twckdly value. In this manner, a memory controller can ensure each rank uses an individual or customized Twckdly value to perform read or write operations.

FIG. 3 illustrates adjusting WCK using a delay in a DRAM chip 120, according to one embodiment herein. As mentioned above, the sync MR 150 stores the difference/delta between the minimum clock delay (e.g., Twckdly value) for the ranks coupled to the same memory controller and the actual clock delay for the rank that includes the DRAM chip 120. This difference/delta is provided by the sync MR 150 to a step control circuit 305. Based on the value in the sync MR 150, the step control circuit 305 determines a number of delays steps to use to further delay the WCK 130 (which has already been delayed by the minimum Twckdly by the controller). In this example, the step control circuit 305 supports 32 different delay values. These delay values can be linear (equally spaced) steps or could be non-linear steps. Further, the step control circuit 305 could support more or less than 32 steps. Notably, if the DRAM chip 120 is in the rank that has the minimum clock delay, then the default value of 0 would be used by the step control circuit 305.

The delay circuit 155 is controlled by the step control circuit 305 to add additional delay to the WCK 130 to generate an adjusted WCK 315. That is, the step control circuit 305 and the delay 155 can perform what was described at block 230 of method 200 to add the difference/delta to the WCK 130.

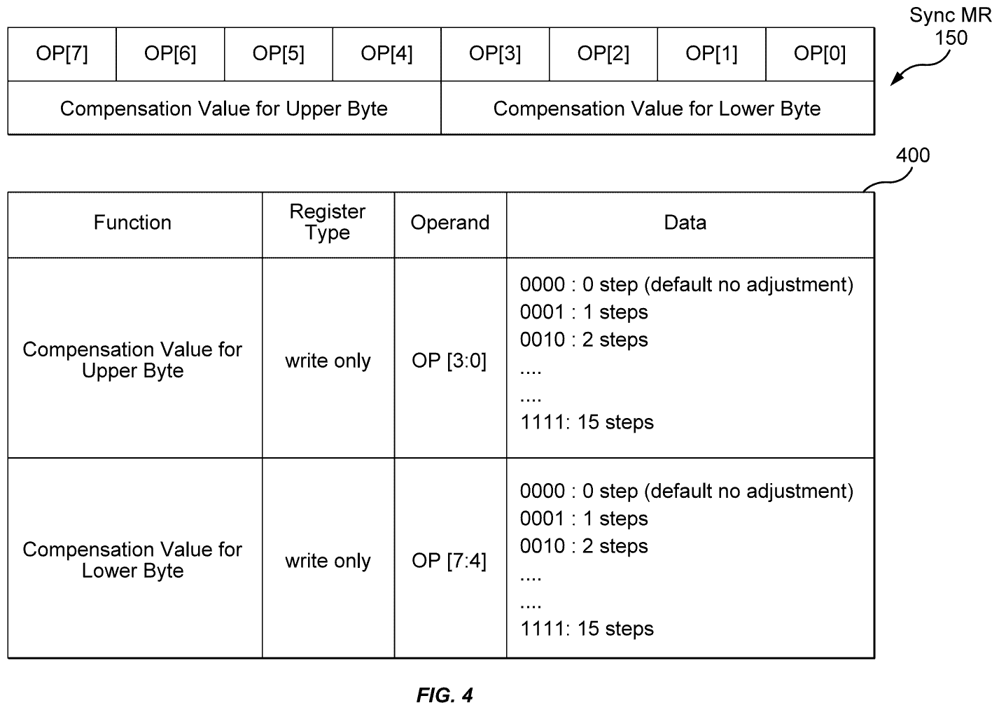

FIG. 4 illustrates the sync MR 150 for storing a delay to compensate for CK-to-WCK timing skew, according to one embodiment herein. FIG. 4 illustrates that the sync MR 150 can include values for compensating for values in upper and lower bytes. The sync MR 150 includes eight operands (OP) in this example. The lower operands (OP[0]-OP[3]) are represented by a compensation value for a lower byte. The upper operands (OP[4]-OP[7]) are represented by a compensation value for an upper byte.

FIG. 4 further includes table 400 which illustrates how these compensation values in the sync MR 150 can be used to support 15 different delay steps (and 32 delay steps when combined). For instance, when the compensation values have a value of 0000, there is no adjustment needed. For example, the rank may be the rank with the minimum Twckdly value, and thus, the rank does not have to further delay the clock received from the memory controller. However, the other values of the compensation values can represent different delays that should be added to the clock received from the memory controller (up to 32 delay steps when combined, where the compensation value for the upper byte represents 15 steps and the compensation value for the low byte represents 15 steps). These 32 possible steps can be used by the step control circuit 305 in FIG. 3 to further delay the WCK 130.

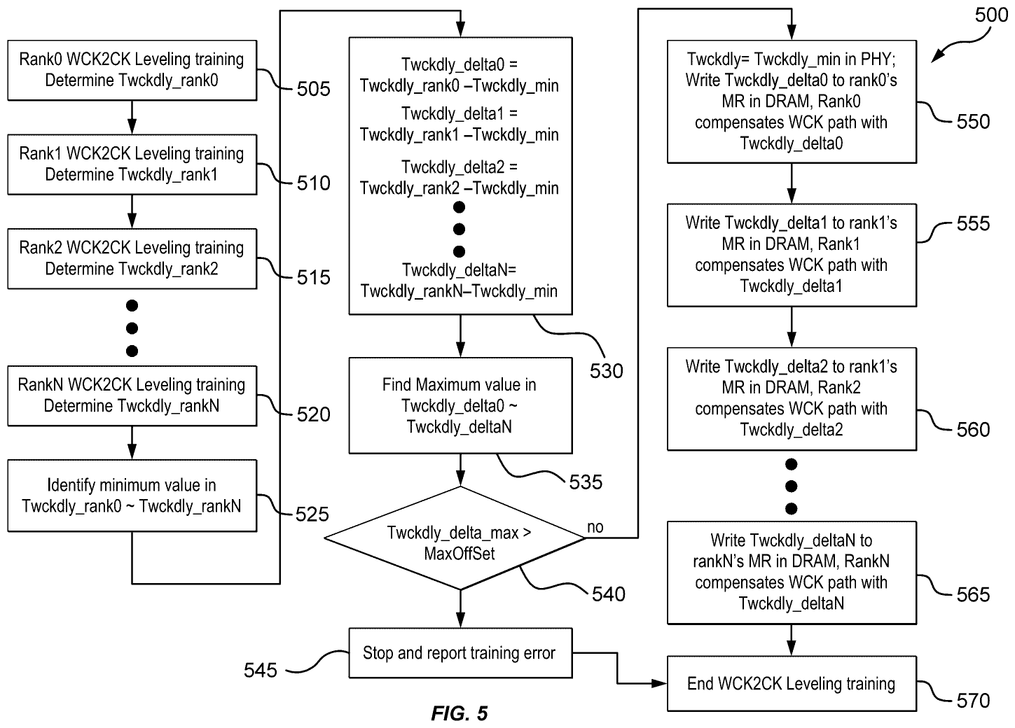

FIG. 5 is a flowchart of a method 500 for providing delays to compensate for CK-to-WCK timing skew affecting WCK2CK synchronous operation, according to one embodiment herein. While the method 200 was described in the context of two ranks coupled to the same memory controller, the method 500 is discussed with N number of ranks coupled to the same memory controller.

At block 505, the WCK2CK level trainer in the memory controller determines the Twckdly value for rank 0 (e.g., Twckdly_rank0) coupled to the memory controller.

At block 510, the WCK2CK level trainer in the memory controller determines the Twckdly value for rank 1 (e.g., Twckdly_rank1) coupled to the memory controller.

At block 515, the WCK2CK level trainer in the memory controller determines the Twckdly value for rank 2 (e.g., Twckdly_rank2) coupled to the memory controller.

At block 520, the WCK2CK level trainer in the memory controller determines the Twckdly value for rank N (e.g, Twckdly_rankN) coupled to the memory controller.

At block 525, the WCK2CK level trainer identifies or detects the minimum Twckdly value for the ranks. That is, the WCK2CK level trainer determines the minimum value of the Twckdly_rank0-N values.

At block 530, the WCK2CK level trainer determines a delta or difference value between each of the Twckdly values and the minimum Twckdly value. For example, the delta between rank 0 and the minimum Twckdly value can be expressed by Twckdly_delta0=Twckdly_rank0−Twckdly_min, the delta between rank 1 and the minimum Twckdly value can be expressed by Twckdly_delta1=Twckdly_rank1−Twckdly_min, and so forth for the N number of ranks.

At block 535, the WCK2CK level trainer identifies a maximum value of the delta values determined at block 530.

At block 540, the WCK2CK level trainer determines or detects whether the maximum value (Twckdly_delta_max) is greater than a maximum offset value (MaxOffSet). For example, the maximum offset may be the largest delay that the delay circuitry shown in FIG. 3 can provide. That is, the WCK2CK level trainer can determine whether one of the delta values is greater than the amount of delay that can be provided by the delay circuitry in the DRAM chips.

If so, the method 500 proceeds to block 545 where the training process is stopped and a training error is reported to the user. The user can then decide whether to proceed (e.g., using the maximum delay that can be provided by the delay circuitry) or to not use the rank. For example, the user may decide not to use any rank that has a delta greater than (exceeds) the maximum offset while the ranks that are at or below the maximum offset are still used. Or the user may decide to use a rank that has a delta greater than the maximum offset, but knowing there may be read and write errors.

However, assuming the maximum delta is equal to or less than the maximum offset, the method 500 proceeds to block 550 where the memory controller transmits the WCK to ranks, which is delayed by the minimum Twckdly delay (e.g., the controller sets the minimum Twckdly in the PHY). As such, the WCK received at the ranks has been delayed by the minimum Twckdly delay.

Moreover, the memory controller writes the individual delta value (Twckdly_delta0) into the sync MR in the rank 0. DRAM chips in rank 0 can use the delta value to compensate for the WCK path as described in FIG. 3. In this manner, rank 0 applies its individual Twckdly value to the WCK.

At block 555, the memory controller writes the individual delta value (Twckdly_delta1) into the sync MR in the rank 1. DRAM chips in rank 1 can use the delta value to compensate for the WCK path as described in FIG. 3. In this manner, rank 1 applies its individual Twckdly value to the WCK.

At block 560, the memory controller writes the individual delta value (Twckdly_delta2) into the sync MR in the rank 2. DRAM chips in rank 2 can use the delta value to compensate for the WCK path as described in FIG. 3. In this manner, rank 2 applies its individual Twckdly value to the WCK.

At block 565, the memory controller writes the individual delta value (Twckdly_deltaN) into the sync MR in the rank N. DRAM chips in rank N can use the delta value to compensate for the WCK path as described in FIG. 3. In this manner, rank N applies its individual Twckdly value to the WCK.

At block 570, the memory controller ends WCK2CK leveling training.

In one embodiment, the memory system operates in the WCK Always on Mode. When this mode is enabled, the WCK buffer is turned on with WCK2CK synchronization and keeps being turned on until SDRAM receives power down, self-refresh power-down or deep-sleep commands or reset. Without this mode, the WCK2CK level trainer has to recalculate the Twckdly values each time the memory system “wakes up” and before performing another read or write. In the Always on Mode, the memory controller keeps WCK toggling (e.g., active) at its full rate after WCK2CK synchronization regardless of DQ operation. Thus, the level training shown in method 500 does not have to be repeated until the memory system leaves the Always on Mode. By remaining in the Always on Mode, the memory controller can save the time to sync WCK between two read or write commands, because it only has to sync once.

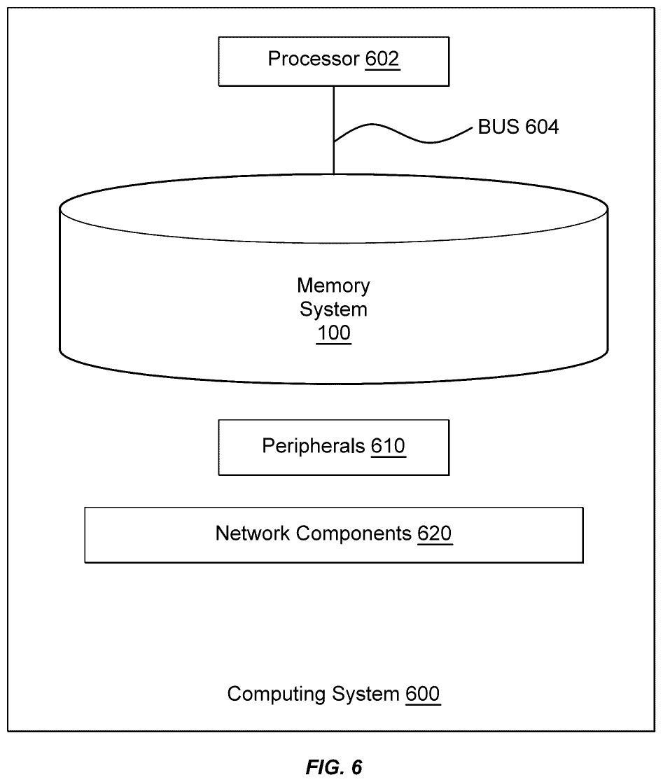

FIG. 6 depicts a block diagram illustrating a computing system, according to one embodiment herein. In an aspect, the computing system 600 can include the memory system 100, as discussed above in relation FIG. 1 above. The computing system 600 includes a processor 602, the memory system 100, peripherals 610 and network components 620. The processor 602 generally retrieves and executes programming instructions stored in the memory system 100. The processor 602 is included to be representative of a single central processing unit (CPU), multiple CPUs, a single CPU having multiple processing cores, graphics processing units (GPUs) having multiple execution paths, and the like.

The processor 602 is communicatively coupled to the memory system 100 via a bus 604. The bus 604 can transmit data serially (e.g., using differential pairs) or in parallel (using multiple wires) to the memory system 100. A memory controller (e.g., the memory controller 105 in FIG. 1) can then perform reads and writes to any number of ranks of DRAM chips (e.g., the ranks 115 in FIG. 1).

The peripherals 610 can include any device that is controlled by the processor 602 such as an input/output (I/O) device, hardware accelerators, printers, external storage devices, and the like.

The network components 620 include the components necessary for the computing system 600 to interface with components over a network (e.g., other control or testing components). The computing system 600 can interface with other elements in a system over a local area network (LAN), for example an enterprise network, a wide area network (WAN), the Internet, or any other suitable network. The network components 620 can include wired, Wi-Fi or cellular network interface components and associated software to facilitate communication between the computing system 600 and a communication network.

In addition to the components already discussed above, the memory system 100 may include other memory devices having blocks of memory associated with physical addresses, such as read only memory (ROM), flash memory, or other types of volatile and/or non-volatile memory. The memory system 100 generally includes program code for performing various functions related to use of the computing system 600. The program code is generally described as various functional “applications” or “services” within the memory system 100, although alternate implementations may have different functions and/or combinations of functions.

The computing system 600 may include one or more computing platforms, such as computer servers for example, which may be co-located, or may form an interactively linked but distributed system, such as a cloud-based system (e.g., a public cloud, a private cloud, a hybrid cloud, or any other suitable cloud-based system). As a result, the processor 602 and memory system 100 may correspond to distributed processor and memory resources within a computing environment.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, circuit or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A memory controller, comprising:
a clock source configured to output a clock signal to a plurality of ranks; and
a level trainer comprising circuitry configured to:
perform level training to generate a first clock delay for a first rank of the plurality of ranks,
perform level training to generate a second clock delay for a second rank of the plurality of ranks, wherein the first clock delay is less than the second clock delay,
write a delta between the second clock delay and the first clock delay in a register in the second rank, and
transmit the clock signal to both the first and second ranks that is delayed by the first clock delay, wherein the second rank is configured to further delay the clock signal using the delta written in the register.

2. The memory controller of claim 1, wherein the clock source is configured to output a data clock (WCK) and a command clock (CK) to the plurality of ranks, wherein the clock signal is the WCK.

3. The memory controller of claim 2, wherein performing level training comprises performing WCK2CK level training, wherein the WCK has a frequency that is a multiple of the CK.

4. The memory controller of claim 1, wherein the first clock delay is a minimum clock delay for all the plurality of ranks.

5. The memory controller of claim 1, wherein the level trainer is configured to:
detect whether the delta exceeds a maximum offset.

6. The memory controller of claim 5, upon detecting that the delta exceeds the maximum offset, the level trainer is configured to stop a training process and report a training error.

7. The memory controller of claim 1, wherein the memory controller is configured to operate in an Always on Mode as a Mode Register Set (MRS) option.

8. The memory controller of claim 1, wherein the register is a mode register (MR).

9. The memory controller of claim 1, wherein the plurality of ranks comprises Low-Power Double Data Rate Synchronous Dynamic Random Access Memory (LPDDR SDRAM).

10. A method, comprising:
performing level training to generate a first clock delay for a first rank of a plurality of ranks of memory chips,
performing level training to generate a second clock delay for a second rank of the plurality of ranks of memory chips, wherein the first clock delay is less than the second clock delay,
write a delta between the second clock delay and the first clock delay in a register in the second rank, and
transmit a clock signal to both the first and second ranks that is delayed by the first clock delay, wherein the second rank is configured to further delay the clock signal using the delta written in the register.

11. The method of claim 10, further comprising:
transmitting a WCK and a CK to the plurality of ranks of memory chips, wherein the clock signal is the WCK.

12. The method of claim 11, wherein performing level training comprises performing WCK2CK level training, wherein the WCK has a frequency that is a multiple of the CK.

13. The method of claim 10, further comprising:
detecting that the first clock delay is a minimum clock delay for all the plurality of ranks of memory chips.

14. The method of claim 10, further comprising:
detecting whether the delta exceeds a maximum offset.

15. The method of claim 14, further comprising:
upon detecting that the delta exceeds the maximum offset:
stopping a training process, and
reporting a training error.

16. The method of claim 10, wherein performing level training is performed with a memory controller coupled to the plurality of ranks of memory chips operating in an Always on Mode as a MRS option.

17. The method of claim 10, wherein the register is a MR.

18. A memory system, comprising:
a plurality of ranks, each comprising a plurality of memory chips; and
a memory controller configured to:
perform level training to generate a first clock delay for a first rank of the plurality of ranks,
perform level training to generate a second clock delay for a second rank of the plurality of ranks, wherein the first clock delay is less than the second clock delay,
write a delta between the second clock delay and the first clock delay in a register in the second rank, and
transmit a clock signal to both the first and second ranks that is delayed by the first clock delay, wherein the second rank is configured to further delay the clock signal using the delta written in the register.

19. The memory system of claim 18, wherein the memory controller comprises a clock source configured to output a data clock (WCK) and a command clock (CK) to the plurality of ranks, wherein the clock signal is the WCK.

20. The memory system of claim 19, wherein performing level training comprises performing WCK2CK level training, wherein the WCK has a frequency that is a multiple of the CK.
